(19) United States
(12) Patent Application Publication
(10) Pub. No.: US 2018/0138305 A1
(43) Pub. Date: May 17, 2018

(54) SEMICONDUCTOR DEVICE AND METHOD OF MANUFACTURING THE SAME

(71) Applicant: Gpower Semiconductor, Inc., Suzhou (CN)

(72) Inventors: Guangmin DENG, Suzhou (CN); Yi PEI, Suzhou (CN)

(21) Appl. No.: 15/412,653

(22) Filed: Jan. 23, 2017

(30) Foreign Application Priority Data
Nov. 15, 2016 (CN) 201611005431.2

(51) Int. Cl. H01L 29/778; H01L 29/66; H01L 29/423; H01L 29/51; H01L 21/02; H01L 29/20

(52) U.S. Cl. CPC H01L 29/7787; H01L 29/66462; H01L 29/2003; H01L 29/517; H01L 21/0254; H01L 29/4236

(57) ABSTRACT

A semiconductor device comprises: a substrate; a semiconductor layer on the substrate; and a gallium nitride cap layer on the semiconductor layer. The gallium nitride cap layer has a thickness of 3 nm to 5.8 nm.

### CROSS-REFERENCE TO RELATED APPLICATIONS

This application claims the benefit and priority of Chinese patent application No. 201611005431.2 filed on Nov. 15, 2016, the entire content of which is incorporated herein by reference.

### TECHNICAL FIELD

The disclosed embodiments relate to semiconductor technology, and more particularly to a semiconductor device and a method of manufacturing the same.

### BACKGROUND

A critical breakdown field intensity of the third-generation semiconductor gallium nitride (GaN), as high as 3 MV/cm, is much higher than that of the first-generation semiconductor silicon (Si) and that of the second-generation semiconductor gallium arsenide (GaAs), and therefore electronic devices made of gallium nitride can withstand high voltages. In addition, gallium nitride can form heterojunction structures with other gallium compound semiconductors (group III nitride semiconductors). Due to the strong spontaneous polarization effect and piezoelectric polarization effect of the group III nitride semiconductors, a two-dimensional electron gas (2DEG) channel with high electron concentration can be formed near an interface of the heterojunction structure. Such a heterojunction structure effectively reduces ionization impurity scattering, so electron mobility within the channel is greatly improved. A gallium nitride high electron mobility transistor (HEMT) made based on this heterojunction structure can turn on a high current at a high frequency, and has a very low on-resistance. These characteristics make the gallium nitride HEMT particularly suitable to produce high-frequency high-power RF devices and high-voltage high-current switching devices.

Since electrons in the two-dimensional electron gas channel have very high mobility, a switching speed of a gallium nitride HEMT is greatly increased compared with a silicon device. Furthermore, a high concentration of two-dimensional electron gas also makes the gallium nitride HEMT have a high current density, and thus suitable for high current power devices. In addition, as a wide bandgap semiconductor material, gallium nitride can work at a relatively high temperature. In a high-power working environment, additional cooling devices are generally required to ensure normal operations of silicon devices, while gallium nitride devices do not need additional cooling devices, or the cooling requirements for the gallium nitride devices are relatively easy Therefore, the gallium nitride power devices help to save spaces and costs.

In a gallium nitride transistor, a high voltage is typically applied between a gate electrode and a drain electrode, resulting in a strong electric field at a region between the gate electrode and the drain electrode and near the gate electrode. The strong electric field will cause a current collapse effect of the gallium nitride device. That is, a part of the electrons will be captured by traps or surface states under an off-state voltage stress, the captured electrons cannot be released in time when the device is turned on, resulting in an increase of the open-state resistance, i.e., the dynamic resistance is high. For the gallium nitride power devices, the current collapse effect leads to a high dynamic resistance and a high switching loss of the device, which will be more obvious under high frequencies.

The traps are located at the interfaces between a gallium nitride cap layer, an aluminum gallium nitride barrier layer, a gallium nitride channel layer, a gallium nitride buffer layer as well as other layers. In order to prevent or reduce the current collapse effect caused by the electron traps on surfaces of materials, a passivation process in which a certain dielectric material such as SiN is used to cover the surfaces of the device is usually utilized for a GaN HEMT. A passivation layer made of, e.g., SiN or AlN can reduce or eliminate the current collapse effect by improving the surface state of the material and preventing electrons from accumulating on the surface. However, passivation reduces the surface state, even to 1×10¹¹ cm⁻²eV⁻¹, as well as a recombination rate, therefore a leakage current of the device is increased, which is disadvantageous for the device.

### SUMMARY

In view of this, embodiments of the present invention are directed to a semiconductor device which is capable of preventing or reducing the current collapse effect without an increase of a leakage current of the semiconductor device. Embodiments of the present invention are also directed to a method of manufacturing such a semiconductor device.

According to one or more embodiments of the present invention, there is provided a semiconductor device, comprising: a substrate; a semiconductor layer on the substrate; and a gallium nitride cap layer on the semiconductor layer, wherein the gallium nitride cap layer has a thickness of 3 nm to 5.8 nm.

In a preferred embodiment, the gallium nitride cap layer has a thickness of 4 nm to 5 nm.

In a preferred embodiment, the semiconductor device further comprises: a source electrode and a drain electrode on the gallium nitride cap layer; and a gate electrode between the source electrode and the drain electrode, wherein the source electrode and the drain electrode form ohmic contacts with the semiconductor layer respectively.

In a preferred embodiment, the semiconductor device further comprises: a first insulating dielectric layer disposed between the source electrode and the gate electrode as well as between the drain electrode and the gate electrode; and a second insulating dielectric layer disposed on the first insulating dielectric layer as well as below the gate electrode.

In a preferred embodiment, a part of the second insulating dielectric layer below the gate electrode is disposed between the gate electrode and the gallium nitride cap layer.

In a preferred embodiment, an opening is provided in the gallium nitride cap layer, a bottom end of the gate electrode extends into the opening, and a part of the second insulating dielectric layer below the gate electrode is disposed between the gate electrode and the semiconductor layer.

In a preferred embodiment, the first insulating dielectric layer and the second insulating dielectric layer are formed of one of silicon nitride, silicon oxide, aluminum oxide and hafnium oxide, or any combination thereof.

In a preferred embodiment, the semiconductor layer comprises a buffer layer, a channel layer and a barrier layer sequentially stacked on the substrate, two-dimensional electron gas is formed at an interface between the channel layer and the barrier layer.

In a preferred embodiment, the barrier layer is formed of a gallium compound semiconductor material or a group III nitride semiconductor material.

In a preferred embodiment, the buffer layer has a thickness of 3 μm to 10 μm.

In a preferred embodiment, the buffer layer comprises a multilayer of aluminum nitride and/or a multilayer of aluminum gallium nitride.

According to one or more embodiments of the present invention, there is also provided a method of manufacturing a semiconductor device, comprising: preparing a substrate; forming a semiconductor layer on the substrate; and forming a gallium nitride cap layer on the semiconductor layer, wherein the gallium nitride cap layer has a thickness of 3 nm to 5.8 nm.

In a preferred embodiment, the gallium nitride cap layer has a thickness of 4 nm to 5 nm.

In a preferred embodiment, the method further comprises: forming a source electrode and a drain electrode on the gallium nitride cap layer; and forming a gate electrode between the source electrode and the drain electrode, wherein the source electrode and the drain electrode form ohmic contacts with the semiconductor layer respectively.

In a preferred embodiment, the method further comprises: forming a first insulating dielectric layer between the source electrode and the gate electrode as well as between the drain electrode and the gate electrode; and forming a second insulating dielectric layer on the first insulating dielectric layer as well as below the gate electrode.

In a preferred embodiment, a part of the second insulating dielectric layer below the gate electrode is disposed between the gate electrode and the gallium nitride cap layer.

In a preferred embodiment, an opening is provided in the gallium nitride cap layer, a bottom end of the gate electrode extends into the opening, and a part of the second insulating dielectric layer below the gate electrode is disposed between the gate electrode and the semiconductor layer.

In a preferred embodiment, the semiconductor layer comprises a buffer layer, a channel layer and a barrier layer sequentially stacked on the substrate, two-dimensional electron gas is formed at an interface between the channel layer and the barrier layer.

In a preferred embodiment, the barrier layer is formed of a gallium compound semiconductor material or a group III nitride semiconductor material.

In a preferred embodiment, the buffer layer has a thickness of 3 μm to 10 μm, and the buffer layer comprises a multilayer of aluminum nitride and/or a multilayer of aluminum gallium nitride.

According to embodiments of the present invention, a gallium nitride cap layer having a thickness of 3 nm to 5.8 nm is utilized, which effectively decreases the surface defects of the barrier layer and prevents the introduction of defects by the oxygen reaction between the barrier layer and the air. On the other hand, negative polarization charges between the gallium nitride cap layer and the aluminum gallium nitrogen lead to enhancement of the electric field in the aluminum gallium nitride, so that the probability that the electrons captured in the defects are released at a high field is high, and thus the dynamic resistance of the device can be reduced.

In other words, according to embodiments of the present invention, by utilizing a proper gallium nitride cap layer having a thickness of 3 nm to 5.8 nm, the current collapse effect can be effectively reduced or substantially prevented. Therefore, there is no need to implement a passivation process to reduce or prevent the current collapse effect, and there will be no increase of the leakage current of the device caused by such a passivation process.

### BRIEF DESCRIPTION OF DRAWINGS

These and other aspects will become apparent and more readily appreciated from the following description of the embodiments, taken in conjunction with the accompanying drawings in which:

FIG. 1 is a schematic structural view illustrating a semiconductor device according to a first embodiment of the present invention;

FIG. 2 is a graph showing a relationship between a drain-source current and a drain-source voltage when the semiconductor device is turned off according to the embodiment of the present invention;

FIG. 3 is a parameter table showing influence of a thickness of a gallium nitride cap layer on a resistance increase value in the semiconductor device according to the embodiment of the present invention;

FIG. 4 (a) is an energy band diagram showing energy bands for gallium nitride cap layers with different thicknesses according to the embodiment of the present invention;

FIG. 4(b) shows electron concentrations for gallium nitride cap layers with different thicknesses according to the embodiment of the present invention;

FIG. 4(c) shows hole concentrations for gallium nitride cap layers with different thicknesses according to the embodiment of the present invention;

FIG. 4(d) is a graph showing percent increase in sheet resistances of gallium nitride cap layers with different thicknesses with respect to the gallium nitride cap layer with a thickness of 2.4 nm according to the embodiment of the present invention; and

FIG. 5 is a schematic structural view illustrating a semiconductor device according to a second embodiment of the present invention.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein.

Accordingly, the embodiments are merely described below, by referring to the figures, to explain aspects of the present description.

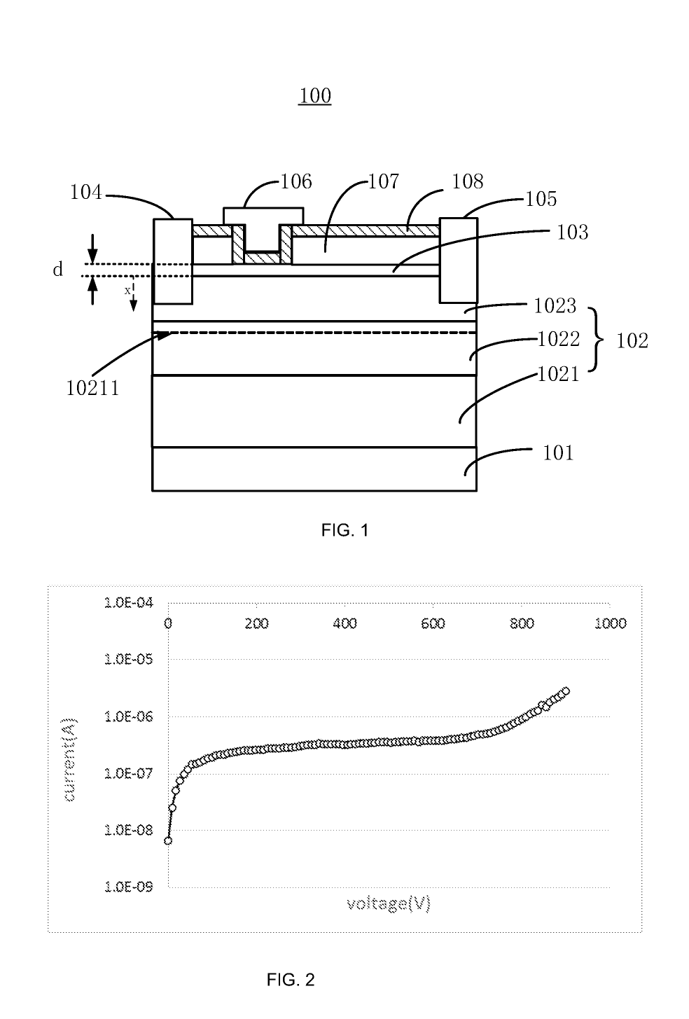

Hereinafter a first embodiment of the present invention will be described in detail with reference to FIGS. 1-4(d).

FIG. 1 is a schematic structural view illustrating a semiconductor device according to a first embodiment of the present invention. As shown in FIG. 1, a semiconductor device 100 includes a substrate 101, a semiconductor layer 102 and a gallium nitride cap layer 103. The semiconductor device 100 according to the embodiment of the present invention may be, but is not limited to, a gallium nitride device.

In the present embodiment, the substrate 101 may be formed of any of sapphire, silicon carbide (SiC), silicon nitride (SiN) and silicon (Si), or any other material suitable for growth of group III nitride materials known to those skilled in the art, and the present invention is not limited thereto. The substrate 101 may be made with any of Chemical Vapor Deposition (CVD), Vapor Phase Epitaxy (VPE), Metal-Organic Chemical Vapor Deposition (MOCVD), Low Pressure Chemical Vapor Deposition (LPCVD), Plasma Enhanced Chemical Vapor Deposition (PECVD), Pulsed Laser Deposition (PLD), atomic layer epitaxy, Molecular Beam Epitaxy (MBE), sputtering, evaporation, and the like. It should be noted that the materials and growing methods used for the substrate 101 according to the embodiment of the present invention are no limited thereto.

A semiconductor layer 102 is formed on the substrate 101. In this embodiment, the semiconductor layer 102 may be formed of a group III-V compound. Preferably, the semiconductor layer 102 includes a nucleation layer (not shown), a buffer layer 1021, a channel layer 1022 and a barrier layer 1023 stacked in this order from the bottom. Two-dimensional electron gas 10211 as shown by a dotted line in FIG. 1 is formed at an interface between the channel layer 1022 and the barrier layer 1023. In the preferred embodiment, the channel layer 1022 and the barrier layer 1023 form a heterojunction structure, and the two-dimensional electron gas 10211 is formed at a heterojunction interface.

The buffer layer 1021 is used to reduce high dislocation density and microcracking of the substrate and the gallium nitride epitaxial material due to lattice misalignment and thermal dislocation. The buffer layer 1021 may be grown using a super lattice buffer layer growing technique or a multi-buffer layer growing technique. If the buffer layer 1021 is grown using a super lattice buffer layer growing technique, a plurality of thin aluminum nitride layers and a plurality of thin aluminum gallium nitride layers may be grown alternately firstly, and then a thick gallium nitride buffer layer may be grown thereon. If the buffer layer 1021 is grown using a multi-buffer layer growing technique, an aluminum nitride buffer layer and a plurality of aluminum gallium nitride buffer layers on the aluminum nitride buffer layer are be grown firstly. Here, the different aluminum gallium nitride buffer layers have different aluminum concentrations, and the aluminum gallium nitride buffer layer adjacent to the aluminum nitride layer has the highest aluminum concentration. And then a gallium nitride buffer layer is further grown thereon. In one example, a thickness of the buffer layer 1021 may be 3 μm to 10 μm in order to manufacture a 600 V to 1200 V device. Preferably, a buffer layer 1021 of a 600 V device has a thickness of 3.8 μm to 4.8 μm. FIG. 2 is a graph showing a relationship between a drain-source current and a drain-source voltage when a semiconductor device comprising a buffer layer with a thickness of 4.5 μm is turned off, where the abscissa represents the drain-source voltage and the ordinate represents the drain-source current. It could be seen from FIG. 2 that the drain-source current of the device is less than 1 μA when a voltage of 600 V is applied. In another example, a thickness of the buffer layer 1021 is preferably less than 10 μm in order to manufacture a 900 V to 1200 V device.

The barrier layer 1023 may be formed of any semiconductor material capable of forming a heterojunction structure with the channel layer 1022, including gallium compound semiconductor materials or group III nitride semiconductor materials such as InₓAl_{y}Ga_{z}N, where 0≤x≤1, 0≤y≤1, and 0≤z≤1.

A gallium nitride cap layer 103 is formed on the semiconductor layer 102. In this embodiment, a thickness d of the gallium nitride cap layer 103 is greater than or equal to 3 nm and less than or equal to 5.8 nm. The inventors of the present invention conducted a large number of experiments using a plurality of gallium nitride cap layers 103 having different thicknesses, and found that a resistance increase value ΔRon decreases with an increase in the thickness of the gallium nitride cap layer 103 after a 300 V stress is applied.

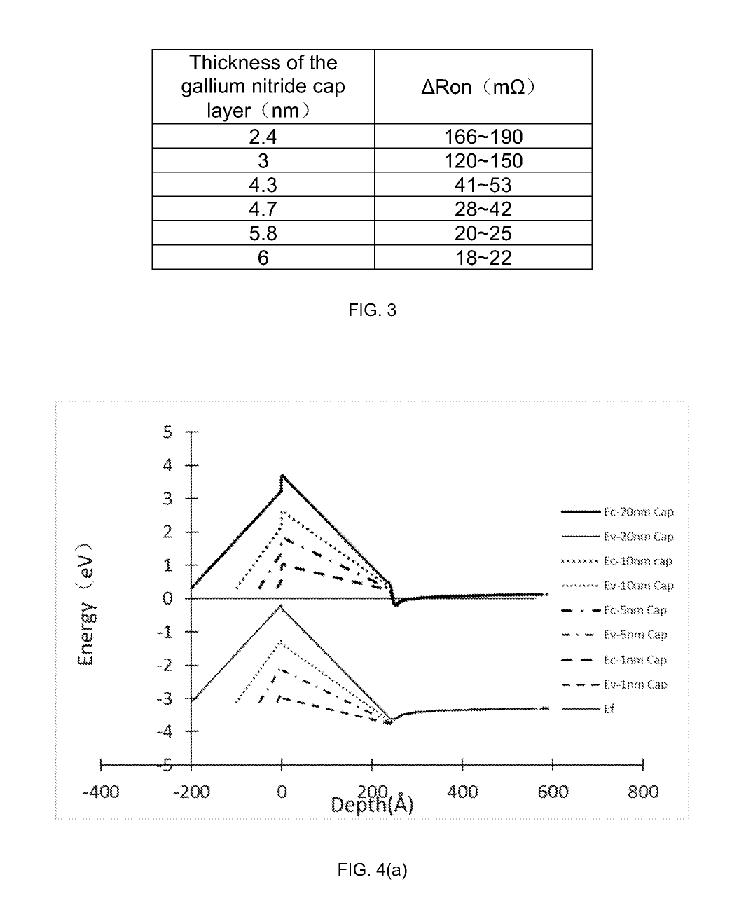

On the one hand, a gallium nitride cap layer 103 having a relatively large thickness can more effectively decrease the surface defections of the barrier layer 1023 and avoid the introduction of defects by the oxygen reaction between AlGaN and the air. As shown in FIG. 3, the resistance increase value of the gallium nitride cap layer 103 decreases as the thickness of the gallium nitride cap layer 103 increases. On the other hand, negative polarization charges between the gallium nitride cap layer 103 and the aluminum gallium nitrogen lead to enhancement of the electric field in the aluminum gallium nitride and decrease in the two-dimensional electron gas concentration in the channel, resulting in an increase in the on-resistance. The probability that the electrons captured in the defects are released at a high field is high, so that the dynamic resistance of the device is reduced.

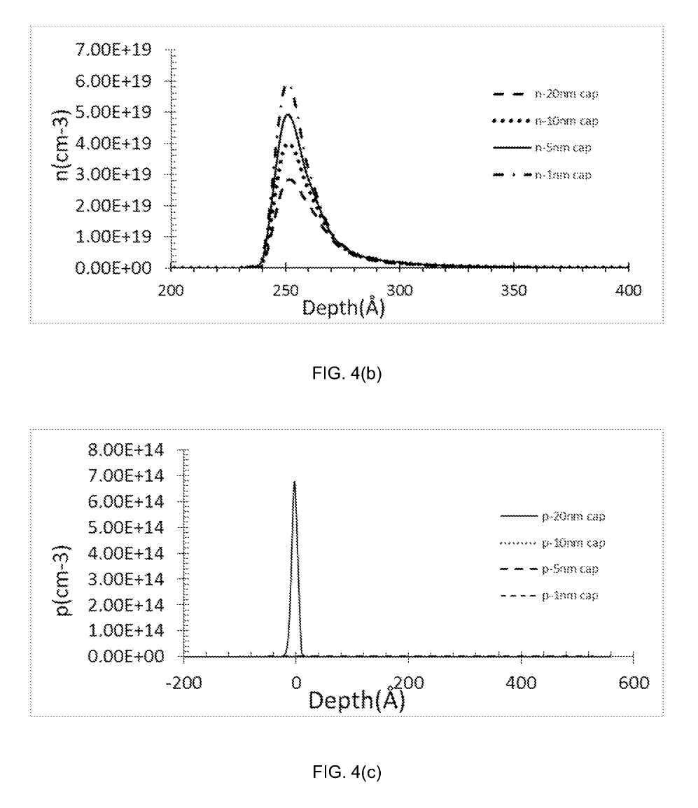

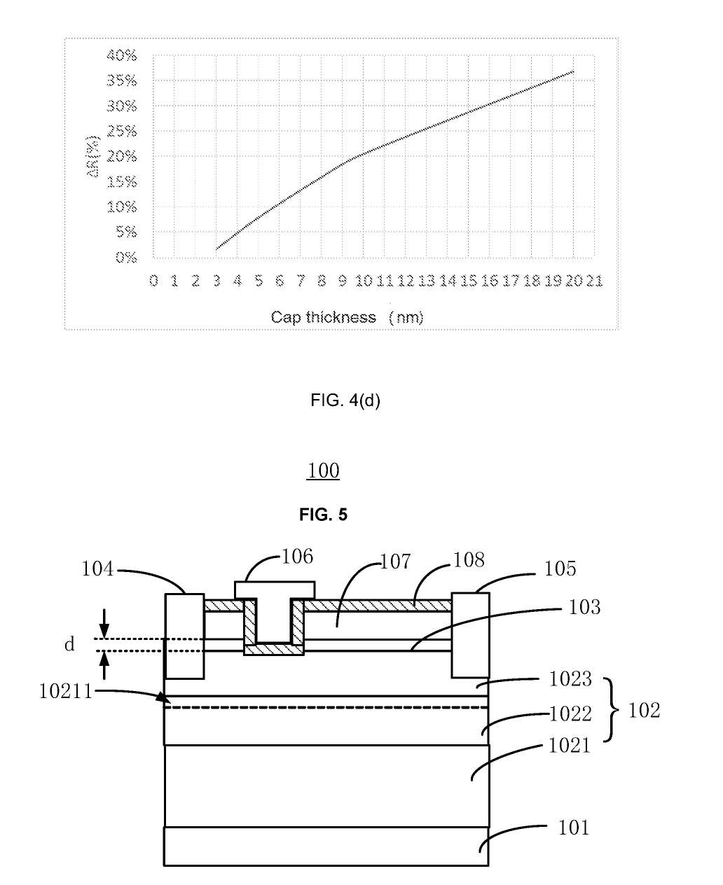

For example, when the structure shown in FIG. 1 is simulated, the energy band diagram corresponding to the gallium nitride cap layers 103 having the thicknesses of 20 nm, 10 nm, 5 nm and 1 nm is shown in FIG. 4 (a) in which the zero position along the x direction shown in FIG. 1 corresponds to the interface between the gallium nitride cap layer 103 and the barrier layer 1023. As can be seen from the energy band diagram shown in FIG. 4(a), the electric field at the barrier layer 1023 gradually increases as the thickness of the gallium nitride cap layer 103 increases. In FIG. 4 (a), Ec represents conduction band, Ev represents valence band, and Ef represents Fermi level. The abscissa Depth represents the depth in the x direction having a unit as Å, and the ordinate Energy represents the energy having a unit as eV.

The electron concentration near the interface between the barrier layer 1023 and the channel layer 1022 is shown in FIG. 4(b). It could be seen from FIG. 4(b) that the concentration of the two-dimensional electron gas in the channel decreases as the thickness of the gallium nitride cap layer 103 increases. The hole concentration along the x direction is shown in FIG. 4(c). It could be seen from FIG. 4(c) that the hole concentration at the interface between the gallium nitride cap layer 103 and the barrier layer 1023 reaches 7×10¹⁴ cm⁻³ when the gallium nitride cap layer 103 has a thickness of 20 nm.

From FIG. 3, when the cap thickness, i.e., the thickness of the gallium nitride cap layer 103, is less than 3 nm, the increase and the range of variation of the dynamic resistance are significantly larger than those when the cap thickness is between 3 nm and 5.8 nm. When the cap thickness is 3 nm, the ΔRon is reduced by about 30% compared to the situation when the cap thickness is 2.4 nm. When the cap thickness is 5.8 nm, the ΔRon is reduced by about 88% compared to the situation when the cap thickness is 2.4 nm. And when the cap thickness is greater than 5.8 nm, the decrease of the dynamic resistance is not obvious.

The abscissa in FIG. 4(d) represents the thickness of the gallium nitride cap layer 103, while the ordinate represents percent increase in sheet resistances of gallium nitride cap layers 103 with different thicknesses with respect to the gallium nitride cap layer 103 with a thickness of 2.4 nm. From FIGS. 4(a) to 4(d), it can be seen that the concentration of the two-dimensional electron gas increases as the thickness of the gallium nitride cap layer 103 increases, resulting in an increase of the sheet resistance of the device. For example, when the cap thickness is 5.8 nm, the sheet resistance is increased by 8% compared to the situation when the cap thickness is 2.4 nm. When the cap thickness is 20 nm, the sheet resistance is increased by 37% compared to the situation when the cap thickness is 2.4 nm.

To sum up, in order to obtain a small dynamic resistance, the thickness of the cap layer should be increased, however, the increase of the thickness of the cap layer will result in an increase in sheet resistance. Therefore, in order to optimize both of the dynamic resistance and the on-resistance, the inventors conducted a large number of experiments and found that a good effect will be achieved if the gallium nitride cap layer 103 is designed to have a thickness of 3 nm to 5.8 nm. In addition, from FIGS. 3-4(c), the above effect is more apparent when the cap thickness is 4 nm to 5 nm. Therefore, the gallium nitride cap layer 103 preferably has a thickness of 4 nm to 5 nm.

Furthermore, the semiconductor device 100 further includes a source electrode 104 and a drain electrode 105 on the gallium nitride cap layer 103, and a gate electrode 106 on the semiconductor layer 102 between the source electrode 104 and the drain electrode 105. The source electrode 104 and the drain electrode 105 are located on opposite ends of the gallium nitride cap layer 103. In the present embodiment, the source electrode 104 and the semiconductor layer 102 form an ohmic contact, and the drain electrode 105 and the semiconductor layer 102 form an ohmic contact. The source electrode 104 and the drain electrode 105 may be formed of a metal material or a composite material of a plurality of metals. The gate electrode 106 may be formed of a single layer of metal or stacked layers of metals. The gate electrode 106 may have a rectangular shape or a T-shape.

Preferably, the semiconductor device 100 further comprises a first insulating dielectric layer 107 and a second insulating dielectric layer 108. The first insulating dielectric layer 107 includes a portion between the source electrode 104 and the gate electrode 106 and another portion between the drain electrode 105 and the gate electrode 106. The second insulating dielectric layer 108 covers the first insulating dielectric layer 107, insulates the source electrode 104 and the gate electrode 106 from each other and insulates the drain electrode 105 and the gate electrode 106 from each other. The gate electrode 106, the first insulating dielectric layer 107 and the gallium nitride cap layer 103 form a Metal-Insulator-Semiconductor (MIS) structure.

In this embodiment, the first insulating dielectric layer 107 and the second insulating dielectric layer 108 may be formed of any of silicon nitride, silicon oxide, aluminum oxide and hafnium oxide, or any combination thereof.

Hereinafter a second embodiment will be described in detail with reference to FIG. 5. Most elements in the second embodiment are the same as or similar to those in the first embodiment, and repeated description thereof will be omitted.

FIG. 5 is a schematic structural view illustrating a semiconductor device according to the second embodiment of the present invention. As shown in FIG. 5, different from the first embodiment, the MIS structure in the second embodiment is formed of the gate electrode 106, the second insulating dielectric layer 108 and the barrier layer 1023. A part of the gallium nitride cap layer 103 below the gate electrode 106 is removed so as to reduce the leakage current between the source electrode 104 and the drain electrode 105. In addition, in the turn-off state of the semiconductor device 100, the spike electric field at an edge of the gate electrode 106 appears in the barrier layer 1023, rather than the surface of the gallium nitride cap layer 103, which reduces probability of capture of the electrons by the interface between the gallium nitride cap layer 103 and the passivation layer, i.e., the first insulating dielectric layer 107. In this way, the current collapse effect can be further reduced, while the impact on the current collapse effect by the passivation layer can be reduced.

On the other hand, compared with the first embodiment, by removing a part of the gallium nitride cap layer 103 below the gate electrode 106 through etching, the electron energy level of the conduction band bottom (Ec) in the region below the gate electrode 106 is higher, which avoids capture and accumulation of electrons in the region below the gate electrode 106, avoids drift of the threshold voltage during operation of the device and improves stability of the device. Therefore, the semiconductor device 100 according to the second embodiment has low leakage current, low current collapse effect and high reliability.

In detail, as shown in FIG. 5, an opening matching the shape of the gate electrode 106 is formed in the gallium nitride cap layer 103, the second insulating dielectric layer 108 extends through the opening to the barrier layer 1023 and thus contacts with the barrier layer 1023. A bottom end of the gate electrode 106 extends into the opening and thus contacts with the second insulating dielectric layer 108, so that the gate electrode 106 and the barrier layer 1023 are insulated by the second insulating dielectric layer 108. In this way, the gate electrode 106, the second insulating dielectric layer 108 and the barrier layer 1023 form an MIS structure.

Embodiments of the present invention also provide a method of manufacturing a semiconductor device, comprising: preparing a substrate; forming a channel layer on the substrate; forming a barrier layer on a surface of the channel layer away from the substrate, the channel layer and the barrier layer constituting a semiconductor layer; forming a gallium nitride cap layer having a thickness of 3 nm to 5.8 nm on the barrier layer of the semiconductor layer.

Furthermore, a source electrode and a drain electrode may be formed on the gallium nitride cap layer, and a gate electrode may be formed between the source electrode and the drain electrode. The source electrode and the semiconductor layer form an ohmic contact, the drain electrode and the semiconductor layer form an ohmic contact.

The detailed steps of manufacturing the semiconductor device according to embodiments of the present invention, including the detailed steps of forming the gate electrode, the source electrode and the drain electrode, may refer to those in the prior art and will not be described in detail herein.

As described above, in the semiconductor device 100 according to embodiments of the present invention, a gallium nitride cap layer 103 having a thickness of 3 nm to 5.8 nm is utilized, which effectively decreases the surface defects of the barrier layer 1023 and prevents the introduction of defects by the oxygen reaction between the barrier layer 1023 and the air. On the other hand, negative polarization charges between the gallium nitride cap layer 103 and the aluminum gallium nitrogen lead to enhancement of the electric field in the aluminum gallium nitride, so that the probability that the electrons captured in the defects are released at a high field is high, and thus the dynamic resistance of the device can be reduced.

It will be understood that the embodiments described herein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention as defined by the following claims and their equivalents.

1. A semiconductor device, comprising:
a substrate;
a semiconductor layer on the substrate, the semiconductor layer comprises a barrier layer; and
a gallium nitride cap layer on the barrier layer,
wherein the gallium nitride cap layer has a thickness of 3 nm to 5.8 nm.

2. The semiconductor device of claim 1, wherein the gallium nitride cap layer has a thickness of 4 nm to 5 nm.

3. The semiconductor device of claim 1, further comprising:
a source electrode and a drain electrode on the gallium nitride cap layer; and
a gate electrode between the source electrode and the drain electrode,
wherein the source electrode and the drain electrode form ohmic contacts with the semiconductor layer respectively.

4. The semiconductor device of claim 3, further comprising:
a first insulating dielectric layer disposed between the source electrode and the gate electrode as well as between the drain electrode and the gate electrode; and
a second insulating dielectric layer disposed on the first insulating dielectric layer as well as below the gate electrode.

5. The semiconductor device of claim 4, wherein a part of the second insulating dielectric layer below the gate electrode is disposed between the gate electrode and the gallium nitride cap layer.

6. The semiconductor device of claim 4, wherein an opening is provided in the gallium nitride cap layer, a bottom end of the gate electrode extends into the opening, and a part of the second insulating dielectric layer below the gate electrode is disposed between the gate electrode and the semiconductor layer.

7. The semiconductor device of claim 4, wherein the first insulating dielectric layer and the second insulating dielectric layer are formed of one of silicon nitride, silicon oxide, aluminum oxide and hafnium oxide, or any combination thereof.

8. The semiconductor device of claim 1, wherein the semiconductor layer further comprises a buffer layer and a channel layer, wherein the buffer layer, the channel layer and the barrier layer are sequentially stacked on the substrate, two-dimensional electron gas is formed at an interface between the channel layer and the barrier layer.

9. The semiconductor device of claim 8, wherein the barrier layer is formed of a gallium compound semiconductor material or a group III nitride semiconductor material.

10. The semiconductor device of claim 8, wherein the buffer layer has a thickness of 3 μm to 10 μm.

11. The semiconductor device of claim 8, wherein the buffer layer comprises a multilayer of aluminum nitride and/or a multilayer of aluminum gallium nitride.

12. A method of manufacturing a semiconductor device, comprising:
preparing a substrate;
forming a semiconductor layer on the substrate, the semiconductor layer comprises a barrier layer; and
forming a gallium nitride cap layer on the barrier layer,
wherein the gallium nitride cap layer has a thickness of 3 nm to 5.8 nm.

13. The method of claim 12, wherein the gallium nitride cap layer has a thickness of 4 nm to 5 nm.

14. The method of claim 12, further comprising:
forming a source electrode and a drain electrode on the gallium nitride cap layer; and
forming a gate electrode between the source electrode and the drain electrode,
wherein the source electrode and the drain electrode form ohmic contacts with the semiconductor layer respectively.

15. The method of claim 14, further comprising:
forming a first insulating dielectric layer between the source electrode and the gate electrode as well as between the drain electrode and the gate electrode; and
forming a second insulating dielectric layer on the first insulating dielectric layer as well as below the gate electrode.

16. The method of claim 15, wherein a part of the second insulating dielectric layer below the gate electrode is disposed between the gate electrode and the gallium nitride cap layer.

17. The method of claim 15, wherein an opening is provided in the gallium nitride cap layer, a bottom end of the gate electrode extends into the opening, and a part of the second insulating dielectric layer below the gate electrode is disposed between the gate electrode and the semiconductor layer.

18. The method of claim 12, wherein the semiconductor layer further comprises a buffer layer and a channel layer, wherein the buffer layer, the channel layer and the barrier layer are sequentially stacked on the substrate, two-dimensional electron gas is formed at an interface between the channel layer and the barrier layer.

19. The method of claim 18, wherein the barrier layer is formed of a gallium compound semiconductor material or a group III nitride semiconductor material.

20. The method of claim 18, wherein the buffer layer has a thickness of 3 μm to 10 μm, and the buffer layer comprises a multilayer of aluminum nitride and/or a multilayer of aluminum gallium nitride.
